(19) United States
(12) Patent Application Publication
(10) Pub. No.: US 2009/0258238 A1
(43) Pub. Date: Oct. 15, 2009

(54) SILICIDE FORMATION UTILIZING NI-DOPED COBALT DEPOSITION SOURCE

(75) Inventors: ShinHwa LI, Chandler, AZ (US); Victor Galaviz, Avondale, AZ (US)

Correspondence Address: MCDERMOTT WILL & EMERY LLP, 18191 VON KARMAN AVE., SUITE 500, IRVINE, CA, 92612-7108, US

(73) Assignee: HERAEUS INC., Chandler, AZ (US)

(21) Appl. No.: 12/102,254

(22) Filed: Apr. 14, 2008

(51) Int. Cl. B05D 5/12; B32B 15/04; C23C 14/34; C23C 18/32; C09D 1/00; H01L 21/283; H01L 29/78

(52) U.S. Cl. 428/450; 427/123; 427/124; 204/192.15; 106/1.27; 438/682; 257/384; 257/E21.159; 257/E29.255

(57) ABSTRACT

A method of forming a layer of an electrically conductive metal-silicide material, comprises steps of: providing a Si-containing workpiece; forming a Ni-doped Co layer on a surface of the workpiece, as by sputter deposition utilizing a Ni-doped Co sputtering target; and reacting the Ni-doped Co layer and workpiece. Embodiments include performing a salicide process to form electrically conductive Ni-doped Co silicide functioning as electrically conductive contacts to the gate electrode and source and drain regions of a MOS transistor. Also disclosed are PVD sources, e.g., sputtering targets, comprising Ni-doped Co and utilized for forming the Ni-doped Co layer.

### FIELD OF THE DISCLOSURE

The present disclosure relates to formation of Ni-doped cobalt silicide films by sputter deposition utilizing a Ni-doped cobalt deposition source, e.g., a sputtering target, and to Ni-doped cobalt deposition sources, e.g., sputtering targets. The disclosure enjoys particular utility in the formation of high integration density semiconductor integrated circuit (IC) devices including active devices such as MOS transistors.

### BACKGROUND OF THE DISCLOSURE

The escalating requirements for high density and performance associated with ultra-large scale integration (ULSI) devices necessitate design rules of 0.18 μm and below, such as 0.15 μm and below, increased transistor and circuit speeds, high reliability, and increased manufacturing throughput. The reduction of design features, e.g., of source, drain, and gate regions of transistors formed in or on a common semiconductor substrate, challenges the limitations of conventional contact and interconnection technology, including conventional photolithographic, etching, and deposition techniques.

As a result of the ever-increasing demand for large-scale and ultra-small dimensioned integrated semiconductor devices, self-aligned techniques have become the preferred technology for forming such devices in view of their simplicity and capability of high-density integration. As device dimensions decrease in the deep sub-micron range, both vertically and laterally, many problems arise, especially those caused by an increase in sheet resistance of the contact areas to the source and drain regions and junction leakage as junction layer thickness decreases. To overcome this problem, the use of self-aligned, highly electrically conductive refractory metal silicides, i.e., salicide processing, has become commonplace in the manufacture of integrated circuit semiconductor devices comprising, e.g., MOS type transistors.

Salicide processing involves deposition of a metal that forms an intermetallic compound with silicon, but does not react with silicon oxides, nitrides, or oxynitrides under normal processing conditions. Refractory metals commonly employed in salicide processing include titanium (Ti), nickel (Ni), and cobalt (Co), each of which forms very low resistivity phases with silicon (Si), e.g., TiSi₂, NiSi₂, and CoSi₂.

Deposition of the refractory metals commonly employed in salicide processing, i.e., titanium (Ti), nickel (Ni), and cobalt (Co), each of which forms very low resistivity phases with silicon (Si), e.g., TiSi₂, NiSi₂, and CoSi₂, involves physical vapor deposition (PVD), preferably cathode sputter deposition utilizing a sputtering target, e.g., a magnetron target, comprised of ultra-pure Ti, Ni, or Co. Co is a preferred material for use in silicide/salicide processing in view of the low resistivity and stability of CoSi₂. 5N purity Co sputtering targets containing <˜6 ppm Ni, and generally termed “Ni-free”, are typically utilized in silicide/salicide processing. Disadvantageously, however, such Ni-free 5N purity Co targets are extremely costly to manufacture, primarily due to the difficulty in separating certain elements therefrom, notably Ni, which occur in nature together with Co. More specifically, separation of Ni from Co to reduce Ni levels to <˜6 ppm, as required in the fabrication of Ni-free 5N purity Co deposition source material, requires much additional effort and incurs significantly increased cost. Consequently, current practices for forming high integration density semiconductor IC devices have high manufacturing costs related to the costly nature of the consumable 5N purity Co sputtering targets utilized therein.

In view of the foregoing, there exists a clear need for improved, less costly means and methodology for performing Co-based silicide/salicide processing utilized in the manufacture of high integration density semiconductor IC devices and other devices requiring deposition of Co layers suitable for silicide/salicide processing.

### SUMMARY OF THE DISCLOSURE

An advantage of the present disclosure is an improved method of forming a layer of an electrically conductive refractory metal material.

Another advantage of the present disclosure is an improved method of forming a layer of electrically conductive Ni-doped Co silicide.

Yet another advantage of the present disclosure is an improved method of forming an electrically conductive contact to a semiconductor device, e.g., a MOS transistor.

Still another advantage of the present disclosure is an improved semiconductor device, e.g., a MOS transistor, comprising a contact layer of electrically conductive Ni-doped Co silicide.

A further advantage of the present disclosure is an improved physical vapor deposition (PVD) source, e.g., a sputtering source, comprising Ni-doped Co.

Additional advantages and other features of the present disclosure will be set forth in the description which follows and in part will become apparent to those having ordinary skill in the art upon examination of the following or may be learned from the practice of the present disclosure. The advantages of the present disclosure may be realized and obtained as particularly pointed out in the appended claims.

According to an aspect of the present disclosure, the foregoing and other advantages are obtained in part by an improved method of forming a layer of an electrically conductive refractory metal-silicide material, comprising steps of:

(a) providing a Si-containing workpiece;

(b) forming a Ni-doped Co layer on a surface of the workpiece; and

(c) reacting the Ni-doped Co layer and workpiece to form a layer of electrically conductive Ni-doped Co silicide.

According to embodiments of the present disclosure, step (b) comprises forming the Ni-doped Co layer by means of a physical vapor deposition (PVD) process utilizing a Ni-doped Co deposition source, for example, depositing the Ni-doped Co layer by sputter deposition, e.g., magnetron sputtering, utilizing a Ni-doped Co target.

Embodiments of step (b) according to the present disclosure include utilizing a 10 ppm≦Ni≦10⁵ ppm Ni-doped Co deposition source, preferably a 10 ppm≦Ni≦10⁴ ppm Ni-doped Co deposition source, more preferably a 10 ppm≦Ni≦500 ppm Ni-doped Co deposition source; whereby step (c) respectively comprises forming a Ni-doped Co silicide layer with 10 ppm≦Ni≦10⁵ ppm, preferably a Ni-doped Co silicide layer with 10 ppm≦Ni≦10⁴ ppm, more preferably a Ni-doped Co silicide layer with 10 ppm≦Ni≦500 ppm.

According to embodiments of the present disclosure, step (a) comprises providing a semiconductor device precursor including at least one active device; and step (c) comprises forming an electrically conductive contact layer on the at least one active device. Preferably, step (a) comprises providing a semiconductor device precursor including at least one MOS transistor; and step (c) is a salicide process comprising forming electrically conductive contact layers over at least one of gate electrode and source and drain regions of the at least one MOS transistor.

Another aspect of the present disclosure is a Si-based semiconductor device, comprising a Ni-doped Co silicide layer formed over at least a portion of at least one active region of the device.

According to preferred embodiments of the present disclosure, the device comprises at least one MOS transistor with a Ni-doped Co silicide layer formed over at least one of gate electrode and source and drain regions of the transistor; and the Ni-doped Co silicide layer has 10 ppm≦Ni≦10⁵ ppm, preferably 10 ppm≦Ni≦10⁴ ppm, more preferably 10 ppm≦Ni≦500 ppm.

A further aspect of the present disclosure is an improved physical vapor deposition (PVD) source comprising Ni-doped Co, wherein 10 ppm≦Ni≦10⁵ ppm, preferably 10 ppm≦Ni≦10⁴ ppm, more preferably 10 ppm≦Ni≦500 ppm.

Preferably, the PVD source is a sputtering target, e.g., a magnetron sputtering target.

Additional advantages and aspects of the present disclosure will become readily apparent to those skilled in the art from the following detailed description, wherein embodiments of the present disclosure are shown and described, simply by way of illustration of the best mode contemplated for practicing the present disclosure. As will be described, the present disclosure is capable of other and different embodiments, and its several details are susceptible of modification in various obvious respects, all without departing from the spirit of the present disclosure. Accordingly, the drawing and description are to be regarded as illustrative in nature, and not as limitative.

### BRIEF DESCRIPTION OF THE DRAWINGS

The following detailed description of the present disclosure can best be understood when read in conjunction with the following drawings, in which the various features (e.g., layers) are not necessarily drawn to scale but rather are drawn as to best illustrate the pertinent features, and like reference numerals are employed throughout to designate similar features, wherein:

FIGS. 1(A)-1(E) illustrate, in simplified, cross-sectional schematic form, a sequence of steps for forming MOS transistors utilizing salicide technology.

### DETAILED DESCRIPTION OF THE DISCLOSURE

According to salicide processing, a refractory metal is deposited in uniform thickness over all exposed upper surface features of a Si wafer by means of a physical vapor deposition (PVD) process, preferably cathode sputter deposition utilizing an ultra-pure sputtering target and an ultra-high vacuum, multi-chamber DC magnetron sputtering system. In MOS transistor formation, deposition is generally performed after gate etch and source/drain junction formation. In a less common variant, source/drain junction formation is effected subsequent to refractory metal layer deposition via dopant diffusion through the refractory metal layer into the underlying semiconductor. In either case, after deposition, the refractory metal layer blankets the top surface of the gate electrode, typically formed of heavily-doped polysilicon, the silicon oxide, nitride, or oxynitride sidewall spacers on the opposing side surfaces of the gate electrode, the silicon oxide isolation regions formed in the silicon substrate between adjacent active device regions, and the exposed surfaces of the substrate where the source and drain regions are formed or will be subsequently formed. As a result of thermal processing, e.g., a rapid thermal annealing process (RTA) typically performed in an inert atmosphere, the refractory metal reacts with underlying Si to form electrically conductive silicide layer portions on the top surface of the polysilicon gate electrode and on the exposed surfaces of the substrate where source and drain regions are or will be formed. Unreacted portions of the refractory metal layer, e.g., on the silicon oxide, nitride, or oxynitride sidewall spacers and the silicon oxide isolation regions, are then removed, as by a wet etching process selective to the metal silicide portions. In some instances, e.g., with Co, a first RTA step may be performed at a relatively lower temperature in order to form first-phase CoSi which is then subjected to a second RTA step performed at a relatively high temperature to convert the first-phase CoSi to second-phase, lower resistivity CoSi₂.

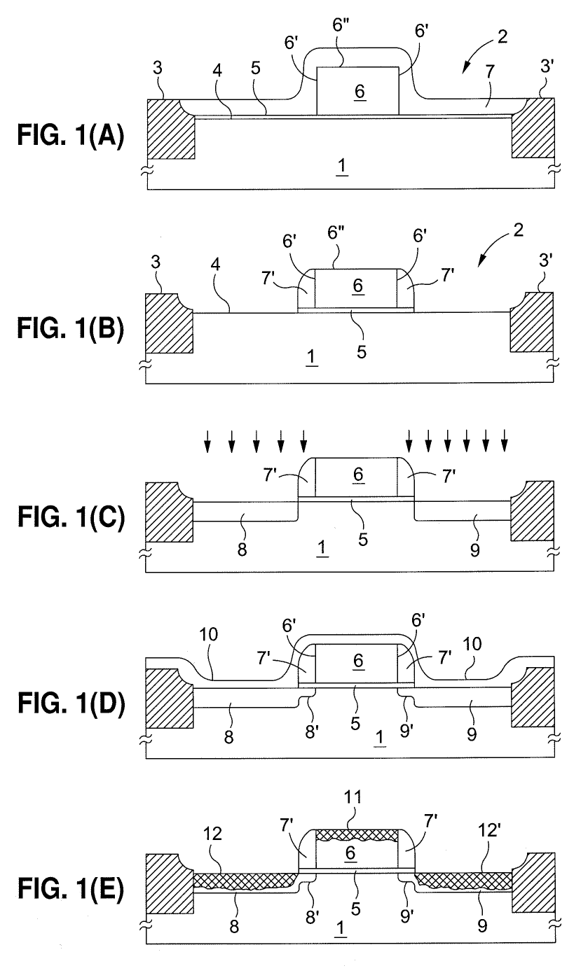

Referring to FIGS. 1(A)-1(E), schematically illustrated therein in simplified, cross-sectional views, are steps in a salicide process for manufacturing MOS transistors and CMOS devices.

Referring more particularly to FIG. 1(A), reference numeral 1 indicates a region or portion of a Si-containing semiconductor substrate of a first conductivity type (p or n), fabricated as a MOS transistor precursor 2 for use in a salicide process scheme. Precursor 2 comprises a plurality of isolation regions, illustratively a pair of regions 3 and 3′ of a silicon oxide, e.g., shallow trench isolation (STI) regions, extending from the substrate surface 4 to a prescribed depth below the surface. A gate insulator layer 5, typically comprising a silicon oxide layer about 25-50 Å thick, is formed on substrate surface 4. Gate electrode 6, typically of heavily-doped polysilicon, is formed over a portion of silicon oxide gate insulator layer 5, and comprises opposing side surfaces 6′, 6′, and top surface 6″. Blanket layer 7 of an insulative material, typically an oxide, nitride, or oxynitride of silicon, is then formed to cover all exposed portions of substrate surface 4 and the exposed surfaces of the various features formed thereon or therein, inter alia, the opposing side surfaces 6′, 6′ and top surface 6″ of gate electrode 6 and the upper surface of STI regions 3, 3′. The thickness of blanket insulative layer 7 is selected so as to provide sidewall spacers 7′, 7′ of desired width on each of the opposing side surfaces 6′, 6′ of the gate electrode 6.

Referring now to FIG. 1(B), MOS precursor structure 2 is then subjected to an anisotropic etching process, as by reactive plasma etching utilizing a fluorocarbon- or fluorohydrocarbon-based plasma, for selectively removing the laterally extending portions of insulative layer 7 and underlying portions of the gate oxide layer 5, whereby sidewall spacers 7′, 7′ of desired width profile are formed along the opposing side surfaces 6′, 6′ of gate electrode 6.

Adverting to FIG. 1(C), moderately- to heavily-doped source and drain junction regions 8 and 9 of conductivity type opposite that of the substrate or epitaxial layer on a suitable substrate are then formed in substrate region 1, as by ion implantation, with sidewall spacers 7′, 7′ acting as implantation masks and setting the lateral displacement length of moderately- to heavily-doped source/drain regions 8 and 9 from the respective proximal edges 6′, 6′ of gate electrode 6.

With reference to FIG. 1(D), in a following step, the thus-formed structure with implanted moderately- to heavily-doped source/drain regions 8, 9 is subjected to a conventional high temperature treatment, typically rapid thermal annealing (RTA), for effecting activation and diffusion of the implanted dopant species, thereby also forming lightly-doped, shallower depth source/drain extension regions 8′, 9′ laterally extending from the respective proximal edges of the moderately- to heavily-doped source/drain regions 8, 9 to just beneath the neighboring edge 6′ of gate electrode 6.

With continued reference to FIG. 1(D), a layer 10 of a refractory metal metal, typically Co, Ni, or Ti, is then formed, as by DC sputtering (e.g., magnetron sputtering) of a Co, Ni, or Ti target, to cover the exposed upper surfaces of precursor 2. Following refractory metal layer 10 deposition, a thermal treatment, typically rapid thermal annealing (RTA), is performed at a temperature and for a time sufficient to convert metal layer 10 to the corresponding electrically conductive metal silicide, e.g., CoSi₂, NiSi₂, or TiSi₂. Since the refractory metal silicide forms only where metal layer 10 is in contact with the underlying silicon, the unreacted portions of metal layer 10 formed over the silicon oxide isolation regions 3 and 3′ and silicon nitride sidewall spacers 7, 7′ are selectively removed, as by a wet etch process.

Referring now to FIG. 1(E), the resulting structure after reaction and removal of unreacted metal comprises metal silicide layer portions 11 and 12, 12′ respectively formed over gate electrode 6 and heavily-doped source and drain regions 8 and 9. Further processing may include, inter alia, formation of metal contact and dielectric insulator layers.

As indicated supra, deposition of high purity cobalt (Co) layers utilized in forming very low resistivity CoSi₂ layers, as in salicide processing for forming electrical contacts in the manufacture of high integration density semiconductor IC and other semiconductor devices, typically involves physical vapor deposition (PVD), preferably cathode sputter deposition utilizing a sputtering target, e.g., a magnetron target, comprised of ultra-pure Co. Co is a preferred material for use in silicide/salicide processing in view of the low resistivity and stability of CoSi₂. 5N purity Co sputtering targets containing <˜6 ppm Ni, and generally designated as “Ni-free”, are typically utilized in silicide/salicide processing. Disadvantageously, however, such Ni-free 5N purity Co targets are extremely costly to manufacture, primarily due to the difficulty in separating certain elements therefrom, notably Ni, which occur in nature together with Co. In particular, separation of Ni from Co to reduce Ni levels to <˜6 ppm, i.e., “nickel-free” levels, as required in the fabrication of “Ni-free” 5N purity Co deposition source material, requires much additional effort and incurs significantly increased cost. Consequently, current practices for forming high integration density semiconductor IC devices and other types of semiconductor devices have high manufacturing costs related to the costly nature of the consumable 5N purity Co sputtering targets utilized therein.

The present disclosure, therefore, has as aims the provision of lower cost Ni-based PVD sources, e.g., sputtering targets, suitable for use in the manufacture of high integration density semiconductor IC devices and other types of semiconductor devices requiring very low resistivity CoSi₂ layers, and improved, lower cost methodology for forming such high integration density semiconductor IC devices and other types of semiconductor devices requiring very low resistivity CoSi₂ layers.

Briefly stated, the present disclosure is based upon the discovery that very low resistivity CoSi₂ layers exhibiting excellent performance characteristics, e.g., as contacts, in IC and other semiconductor device applications can be readily and conveniently formed by use of Ni-doped Co PVD sources, e.g., sputtering sources such as magnetron targets, which Ni-doped Co PVD sources are fabricated at significantly reduced cost vis-à-vis conventional Ni-free (i.e., <6 ppm Ni) PVD sources, primarily due to elimination of the requirement for use of very costly processing techniques and methodologies for reducing Co levels in Ni to achieve “Ni-free” purity levels, i.e., <6 ppm Ni. The use of significantly lower cost Ni-doped Co consumable PVD sources, e.g., sputtering targets, afforded by the present disclosure advantageously translates into lower manufacturing costs of IC and other semiconductor devices.

As utilized throughout the present disclosure and claims, the term “Ni-doped Co” refers to Co containing a minor amount of Ni, i.e., greater than the <6 ppm Ni present in Ni-free Co, i.e., ≧˜10 ppm, but not >˜10⁵ ppm. According to the present disclosure, Ni-doped Co material suitable for use as PVD sources, e.g., sputtering targets, may be formed in different ways, e.g., by limiting removal of Ni naturally occurring in Co during conventional metal refining to achieve a desired Ni level ≧˜10 ppm, hence reducing processing costs, or by introducing an additional amount of Ni to low-doped Co containing Ni to achieve a desired Ni dopant level ≧˜10 ppm.

An illustrative, but non-limitative silicide/salicide process utilizing a Ni-doped Co PVD source, i.e., a magnetron sputtering target comprised of Ni-doped Co, generally corresponds to the process illustrated in FIGS. 1(A)-1(E). Stated in general terms, a process according to the present disclosure for forming a layer of an electrically conductive refractory metal-silicide material, comprises steps of:

(a) providing a Si-containing workpiece;

(b) forming a Ni-doped Co layer on a surface of the workpiece; and

(c) reacting the Ni-doped Co layer and workpiece to form a layer of electrically conductive Ni-doped Co silicide.

According to embodiments of the present disclosure, step (b) comprises forming the Ni-doped Co layer by means of a physical vapor deposition (PVD) process utilizing a Ni-doped Co deposition source, for example, by depositing the Ni-doped Co layer by sputter deposition in conventional manner as shown in FIG. 1(D), e.g., by magnetron sputtering utilizing a Ni-doped Co target. By way of illustration, but not limitation, step (b) may for example comprise utilizing a 10 ppm≦Ni≦10⁵ ppm Ni-doped Co target, preferably a 10 ppm≦Ni≦10⁴ ppm Ni-doped Co target, more preferably a 10 ppm≦Ni≦500 ppm Ni-doped Co target.

Step (c) comprises forming a Ni-doped Co silicide layer in conventional manner as described above in connection with the description of FIG. 1(E), as by rapid thermal annealing (RTA) at a temperature and interval sufficient to convert the Ni-doped Co layer deposited in step (b) to an electrically conductive Ni-doped CoSi₂ layer. The amount of Ni dopant present in the thus-formed Ni-doped CoSi₂ layer will generally correspond to that present in the PVD source, i.e., sputtering target, utilized in performing step (b). Therefore, according to the exemplary embodiment, the Ni-doped CoSi₂ layer will contain 10 ppm≦Ni≦10⁵ ppm, preferably 10 ppm≦Ni≦10⁴ ppm, more preferably 10 ppm≦Ni≦500 ppm.

The Ni-doped Co silicide layers formed according to the present disclosure exhibit properties/characteristics which are fully compatible with the requirements of the product devices, including very low resistivity and thermal stability.

More specifically, according to exemplary embodiments of the present disclosure, step (a) comprises providing a semiconductor device precursor including at least one active device; and step (c) comprises forming an electrically conductive contact layer on the at least one active device. Preferably, step (a) comprises providing a semiconductor device precursor including at least one MOS transistor; and step (c) preferably is a salicide process comprising forming electrically conductive contact layers over at least one of gate electrode and source and drain regions of the at least one MOS transistor.

Another aspect of the present disclosure is a Si-based semiconductor device, such as formed via the above-described process, comprising a Ni-doped Co silicide layer formed over at least a portion of at least one active region of the device. Preferably, the device comprises at least one MOS transistor with a Ni-doped Co silicide layer formed over at least one of gate electrode and source and drain regions of the transistor. By way of illustration only, the amount of Ni dopant in the Ni-doped silicide layer may be 10 ppm≦Ni≦10⁵ ppm, preferably 10 ppm≦Ni≦10⁴ ppm, more preferably 10 ppm≦Ni≦500 ppm, depending upon the Ni content of the Ni-doped Co PVD source utilized for the process methodology.

A further aspect of the present disclosure is improved physical vapor deposition (PVD) sources comprising Ni-doped Co. By way of illustration, the amount of Ni dopant in the PVD source may be 10 ppm≦Ni≦10⁵ ppm, preferably 10 ppm≦Ni≦10⁴ ppm, more preferably 10 ppm≦Ni≦500 ppm. Preferably, the PVD source is in the form of a sputtering target, e.g., a magnetron sputtering target.

In summary, the present disclosure provides significantly lower cost Ni-based PVD sources, e.g., sputtering targets, which lower cost PVD sources advantageously facilitate lower cost manufacture of high integration density semiconductor IC devices and other types of semiconductor devices. The Ni-doped Co PVD sources provided by the present disclosure enjoy particular use in the formation of highly electrically conductive silicide contact layers to active semiconductor devices (e.g., MOS transistors), as by salicide processing methodology.

In the previous description, numerous specific details are set forth, such as specific materials, structures, processes, etc., in order to provide a better understanding of the present of the present disclosure. However, the present disclosure can be practiced without resorting to the details specifically set forth herein. In other instances, well-known processing techniques and structures have not been described in order not to unnecessarily obscure the present disclosure.

Only the preferred embodiments of the present disclosure and but a few examples of its versatility are shown and described in the present disclosure. It is to be understood that the present disclosure is capable of use in various other combinations and environments and is susceptible of changes and/or modification within the scope of the concept(s) as expressed herein.

What is claimed is:

1. A method of forming a layer of an electrically conductive refractory metal-silicide material, comprising steps of:
(a) providing a Si-containing workpiece;
(b) forming a Ni-doped Co layer on a surface of said workpiece; and
(c) reacting said Ni-doped Co layer and said workpiece to form a layer of electrically conductive Ni-doped Co silicide.

2. The method according to claim 1, wherein:
step (b) comprises forming said Ni-doped Co layer by means of a physical vapor deposition (PVD) process utilizing a Ni-doped Co deposition source.

3. The method according to claim 2, wherein:
step (b) comprises sputter depositing said Ni-doped Co layer utilizing a Ni-doped Co target.

4. The method according to claim 3, wherein:
step (b) comprises magnetron sputter depositing said Ni-doped Co layer utilizing a Ni-doped Co target.

5. The method according to claim 2, wherein:
step (b) comprises utilizing a 10 ppm≦Ni≦10⁵ ppm Ni-doped Co deposition source.

6. The method according to claim 2, wherein:
step (b) comprises utilizing a 10 ppm≦Ni≦10⁴ ppm Ni-doped Co deposition source.

7. The method according to claim 2, wherein:
step (b) comprises utilizing a 10 ppm≦Ni≦500 ppm Ni-doped Co deposition source.

8. The method according to claim 1, wherein:
step (c) comprises forming a Ni-doped Co silicide layer with 10 ppm≦Ni≦10⁵ ppm.

9. The method according to claim 1, wherein:
step (c) comprises forming a Ni-doped Co silicide layer with 10 ppm≦Ni≦10⁴ ppm.

10. The method according to claim 1, wherein:
step (c) comprises forming a Ni-doped Co silicide layer with 10 ppm≦Ni≦500 ppm.

11. The method according to claim 1, wherein:
step (a) comprises providing a semiconductor device precursor including at least one active device; and
step (c) comprises forming an electrically conductive contact layer on said at least one active device.

12. The method according to claim 11, wherein:
step (a) comprises providing a semiconductor device precursor including at least one MOS transistor; and
step (c) comprises forming electrically conductive contact layers over at least one of gate electrode and source and drain regions of said at least one MOS transistor.

13. The method according to claim 12, wherein:
step (c) is part of a salicide process.

14. A Si-based semiconductor device, comprising a Ni-doped Co silicide layer formed over at least a portion of at least one active region of said device.

15. The device as in claim 14, comprising at least one MOS transistor with a said Ni-doped Co silicide layer formed over at least one of gate electrode and source and drain regions of said transistor.

16. The device as in claim 14, wherein said Ni-doped Co silicide layer has 10 ppm≦Ni≦10⁵ ppm.

17. The device as in claim 14, wherein said Ni-doped Co silicide layer has 10 ppm≦Ni≦10⁴ ppm.

18. The device as in claim 14, wherein said Ni-doped Co silicide layer has 10 ppm≦Ni≦500 ppm.

19. A physical vapor deposition (PVD) source comprising Ni-doped Co.

20. The PVD source as in claim 19, wherein 10 ppm≦Ni≦10⁵ ppm.

21. The PVD source as in claim 19, wherein 10 ppm≦Ni≦10⁴ ppm.

22. The PVD source as in claim 19, wherein 10 ppm≦Ni≦500 ppm.

23. The PVD source as in claim 19, in the form of a sputtering target.

24. The PVD source as in claim 23, in the form of a magnetron sputtering target.
